(19) United States
(12) Patent Application Publication
(10) Pub. No.: US 2019/0006625 A1
(43) Pub. Date: Jan. 3, 2019

(54) LIGHT-EMITTING ELEMENT AND DISPLAY DEVICE HAVING THE LIGHT-EMITTING ELEMENT

(71) Applicant: Japan Display Inc., Tokyo (JP)

(72) Inventor: Hironori TOYODA, Tokyo (JP)

(21) Appl. No.: 15/996,571

(22) Filed: Jun. 4, 2018

(30) Foreign Application Priority Data
Jun. 29, 2017 (JP) 2017-127204

(51) Int. Cl. H01L 51/52; H01L 27/32

(52) U.S. Cl. CPC H01L 51/5265; H01L 27/3246; H01L 2251/558; H01L 51/5215; H01L 51/5209

(57) ABSTRACT

Disclosed is a light-emitting element including a reflective electrode, a light-transmitting electrode over the reflective electrode, a partition wall over the light-transmitting electrode, the partition wall having a first opening and a second opening which overlap with the light-transmitting electrode, an electroluminescence layer over the first opening and the second opening, and an opposing electrode over the electroluminescence layer. A thickness of the light-transmitting electrode in a region overlapping with the first opening is smaller than a thickness of the light-transmitting electrode in a region overlapping with the second region.

### CROSS REFERENCE TO RELATED APPLICATIONS

This application is based on and claims the benefit of priority from the prior Japanese Patent Application No. 2017-127204, filed on Jun. 29, 2017, the entire contents of which are incorporated herein by reference.

### FIELD

The present invention relates to a display device and a manufacturing method of the display device. For example, the present invention relates to a display device having an organic light-emitting element in a pixel and a manufacturing method thereof.

### BACKGROUND

An organic EL (Electroluminescence) display device is represented as an example of a display device. An organic EL display device has, as a display element, an organic light-emitting element (hereinafter, referred to as a light-emitting element) in each of a plurality of pixels formed over a substrate. A light-emitting element has a plurality of functional layers containing an organic compound (hereinafter, these functional layers are collectively referred to as an electroluminescence layer or an EL layer) between a pair of electrodes (cathode and anode) and is operated by supplying current between the electrodes.

Light obtained from an electroluminescence layer is repeatedly reflected at interfaces between the electroluminescence layer and electrodes, interfaces between functional layers, or in the electrodes. Therefore, a micro-resonator is formed in a light-emitting element, and the reflected light interferes with each other. Appropriate adjustment of this optical interference with the structure of the micro-resonator enables a variety of properties of the light-emitting element, such as emission efficiency, emission color, and viewing-angle dependency, to be controlled.

Adjustment of optical interference is performed by a variety of methods. For example, the adjustment is carried out by a material or a thickness of each functional layer, a reflectance of an electrode, and an external structure of a light-emitting element. For example, Japanese Patent Application Publications No. 2006-302878 and 2006-302879 disclose that adjustment of emission intensity and emission color is conducted by providing a resonance structure over one of electrodes of a light-emitting element to resonate light emitted from the light-emitting element.

### SUMMARY

An object of an embodiment according to the present invention is to provide a light-emitting element with small variation in property in which properties of the light-emitting element are controlled by reducing influence of variation in thickness of functional layers on optical interference, a display device having the light-emitting element, and a manufacturing method thereof.

An embodiment of the present invention is a light-emitting element. The light-emitting element includes a reflective electrode, a light-transmitting electrode over the reflective electrode, a partition wall over the light-transmitting electrode, the partition wall having a first opening and a second opening which overlap with the light-transmitting electrode, an electroluminescence layer over the first opening and the second opening, and an opposing electrode over the electroluminescence layer. A thickness of the light-transmitting electrode in a region overlapping with the first opening is smaller than a thickness of the light-transmitting electrode in a region overlapping with the second region.

An embodiment of the present invention is a display device including a first pixel and a second pixel. The first pixel possesses a first reflective electrode, a first light-transmitting electrode over the first reflective electrode, a partition wall over the first light-transmitting electrode, the partition wall having a first opening and a second opening which overlap with the first light-transmitting electrode, a first electroluminescence layer overlapping with the first opening and the second opening, and an opposing electrode overlapping with the first electroluminescence layer. The second pixel possesses a second reflective electrode, a second light-transmitting electrode over the second reflective electrode, a second electroluminescence layer over the second light-transmitting electrode, and the opposing electrode overlapping with the second electroluminescence layer. A thickness of the first light-transmitting electrode in a region overlapping with the first opening is smaller than a thickness of the second light-transmitting electrode, and the thickness of the second light-transmitting electrode is larger than a thickness of the first light-transmitting electrode in a region overlapping with the second opening.

An embodiment of the present invention is a display device including a first pixel, a second pixel, and a third pixel. The first pixel possesses a first reflective electrode, a first light-transmitting electrode over the first reflective electrode, a partition wall over the first light-transmitting electrode, the partition wall having a first opening and a second opening which overlap with the first light-transmitting electrode, a first electroluminescence layer overlapping with the first opening and the second opening, and an opposing electrode over the first electroluminescence layer. The second pixel possesses a second reflective electrode, a second light-transmitting electrode over the second reflective electrode, a second electroluminescence layer over the second light-transmitting electrode, and the opposing electrode overlapping with the second electroluminescence layer. The third pixel possesses a third reflective electrode, a third light-transmitting electrode over the third reflective electrode, a third electroluminescence layer over the third light-transmitting electrode, and the opposing electrode over the third electroluminescence layer. A thickness of the first light-transmitting electrode in a region overlapping with the first opening is smaller than a thickness of the second light-transmitting electrode, and the thickness of the second light-transmitting electrode is larger than a thickness of the first light-transmitting electrode in a region overlapping with the second opening.

### BRIEF DESCRIPTION OF DRAWINGS

FIG. 1 is a schematic top view of a display device according to an embodiment;

FIG. 2 is a schematic top view of a pixel of a display device according to an embodiment;

FIG. 3 shows a schematic cross-sectional view of a light-emitting element according to an embodiment;

FIG. 4A and FIG. 4B are schematic diagrams showing a relationship between variation in thickness of an electroluminescence layer and variation in property of an element in a light-emitting element according to an embodiment;

FIG. 5A and FIG. 5B are schematic diagrams showing a relationship between variation in thickness of an electroluminescence layer and variation in property of an element in a light-emitting element according to an embodiment;

FIG. 6 is a schematic cross-sectional view of a light-emitting element according to an embodiment;

FIG. 7 is an equivalent circuit of a pixel of a display device according to an embodiment;

FIG. 8 is a schematic cross-sectional view of a display device according to an embodiment;

FIG. 9A and FIG. 9B are schematic cross-sectional views showing a manufacturing method of a display device according to an embodiment;

FIG. 10A and FIG. 10B are schematic cross-sectional views showing a manufacturing method of a display device according to an embodiment;

FIG. 11A and FIG. 11B are schematic cross-sectional views showing a manufacturing method of a display device according to an embodiment;

FIG. 12 is a schematic top view of a pixel of a display device according to an embodiment; and

FIG. 13A and FIG. 13B are schematic diagrams showing a relationship between variation in thickness of an electroluminescence layer and variation in property of an element in a light-emitting element according to an embodiment.

### DESCRIPTION OF EMBODIMENTS

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the present specification and claims, when a plurality of films is formed by processing one film, the plurality of films may have functions or rules different from each other. However, the plurality of films originates from a film formed as the same layer in the same process and has the same layer structure and the same material. Therefore, the plurality of films is defined as films existing in the same layer.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the present specification and claims, an expression “a structural body is exposed from another structural body” means an aspect where a portion of the structural body is not covered by the other structural body and includes an aspect where the portion which is not covered by the other structural body is covered by yet another structural body.

In the present specification, when a plurality of structural elements similar to one another is discriminately indicated, the structural elements are expressed by using an underscore and a natural number after a reference number. When all of the structural elements are indicated or an arbitrarily selected multiple thereof is expressed indiscriminately, only a reference number is used.

### First Embodiment

In the present embodiment, an explanation is made focusing on a structure of a light-emitting element included in a display device 100 according to an embodiment.

### 1. Outline Structure

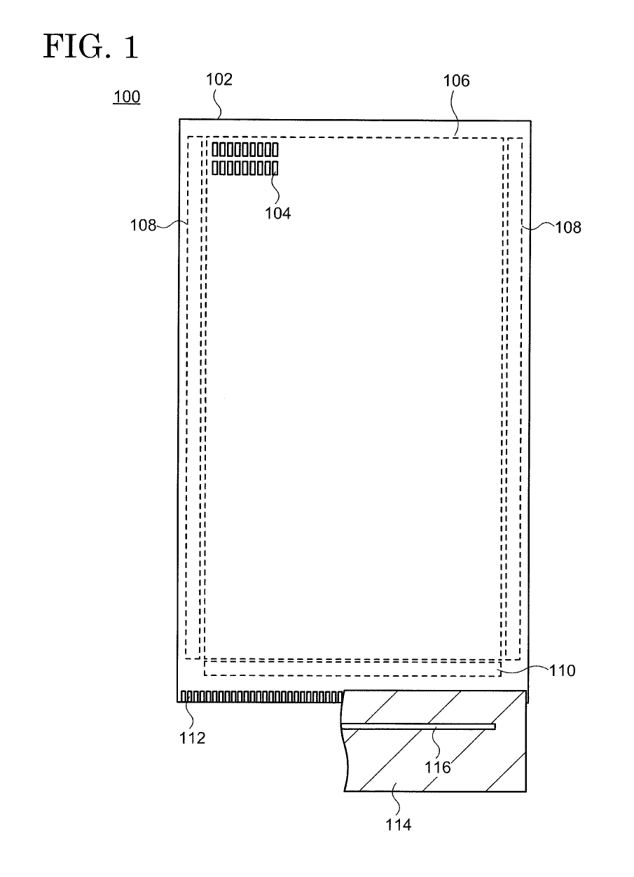

A schematic top view of the display device 100 is shown in FIG. 1. The display device 100 has a substrate 102 over which a plurality of pixel groups 104 is formed. A display region 106 is defined by the plurality of pixel groups 104, and driver circuits for driving the pixel groups 104 are provided in a region (peripheral region) surrounding the display region 106. In the example shown in FIG. 1, two gate-side driver circuits 108 sandwiching the display region 106, and a source-side driver circuit 110 including analogue switches and the like are disposed. Wirings which are not illustrated extend from the display region 106, the gate-side driver circuits 108, and the source-side driver circuit 110 to a side of the substrate 102 and are exposed at an edge portion of the substrate 102 to form terminals 112. The terminals 112 are electrically connected to a connector 114 such as a flexible printed circuit (FPC) substrate. A driver IC 110 for controlling the pixel groups 104 may be mounted over the connector 114 or the substrate 102. Note that the source-side driver circuit 110 may not be arranged in the peripheral region and its function may be realized by the driver IC 110. As described below, each pixel group 104 possesses a plurality of pixels 120 each provided with a light-emitting element 160. The light-emitting elements 160 are controlled by the gate-side driver circuits 108, the source-side driver circuit 110, and the like by which an image is displayed on the display region 106.

### 2. Pixel

### 2-1. Emission Region

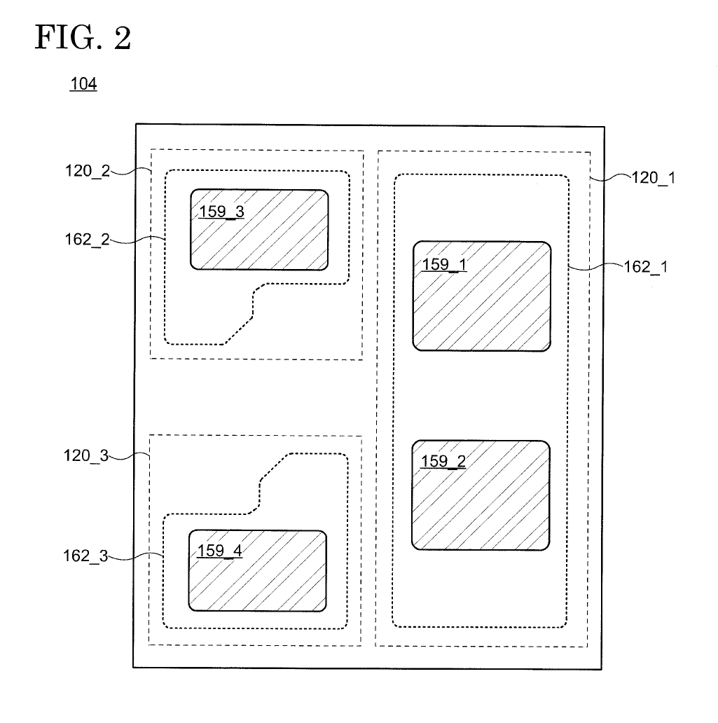

FIG. 2 shows a schematic top view of one pixel group 104. A plurality of pixels 120 is disposed in each pixel group 104, and the light-emitting element 160 is arranged in each pixel 120. The number of the pixels 120 provided in one pixel group 104 is not limited, and an example is shown here where three pixels (first pixel 120_1, second pixel 120_2, and third pixel 120_3) are formed in one pixel group 104. As described below in detail, each pixel 120 has a pixel electrode 162 over which a partition wall 158 (not illustrated in FIG. 1) serving as an insulating film is provided. The partition wall 158 covers edge portions of the pixel electrodes 162 and possesses openings overlapping with the pixel electrodes 162. The pixel electrodes 162 are exposed from the partition wall 158 in these openings to give emission regions 159. In one of the pixels of each pixel group 104 (here, the first pixel 120_1), the partition wall 158 has two openings (first opening and second opening). Therefore, two emission regions (first emission region 159_1 and second emission region 159_2) are formed over the first pixel electrode 162_1. The partition wall 158 has a single opening (third opening and fourth opening) in each of the other pixels (here, the second pixel 120_2 and the third pixel 120_3) to respectively give a third emission region 159_3 and a fourth emission region 159_4 to the second pixel electrode 162_2 and the third pixel electrode 162_3. Note that, in the first pixel 120_1, an equipotential is maintained in the first pixel electrode 162 across the two emission regions 159. Hence, emission is simultaneously obtained through the two emission regions 159 from the light-emitting element 160 in the first pixel 120_1.

Areas of the emission regions 159 (i.e., areas of the openings of the partition wall 158) may be arbitrarily determined. In the example shown in FIG. 1, an area of the first opening is the same or substantially the same as an area of the second opening. Thus, an area of the first emission region 159_1 is the same or substantially the same as an area of the second emission region 159_2. An area of the third opening is also the same or substantially the same as an area of the fourth opening, and therefore, an area of the third emission region 159_3 is the same or substantially the same as an area of the fourth emission region 159_4.

### 2-2. Light-Emitting Element

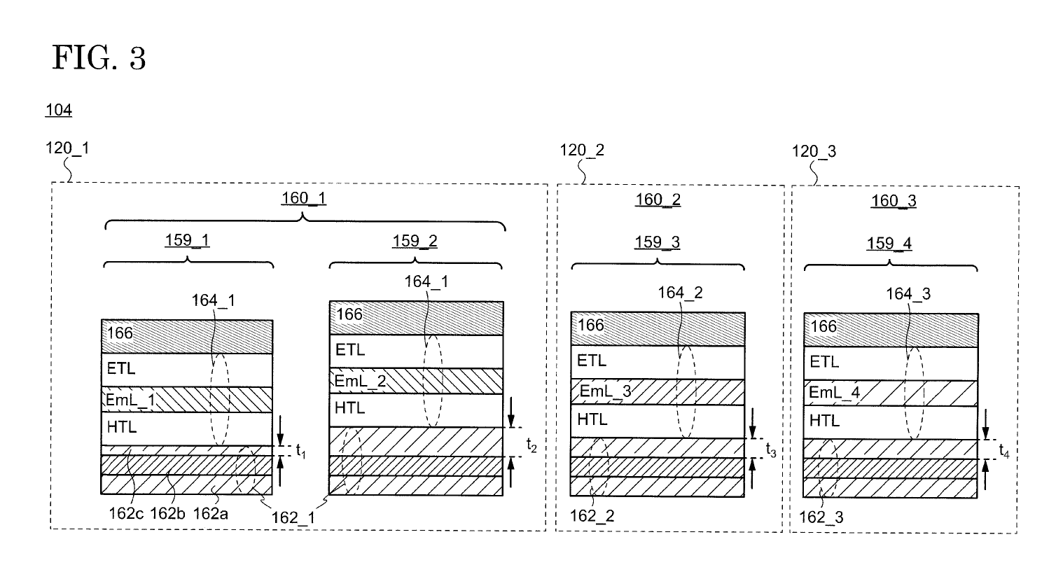

Schematic cross-sectional views of the light-emitting elements (first light-emitting element 160_1 to third light-emitting element 160_3) of the first pixel 120_1 to the third pixel 120_3 included in one pixel group 104 are shown in FIG. 3. Here, the structures of the light-emitting elements 160 in the emission regions 159 are illustrated. These light-emitting elements 160 each have a pixel electrode 162 over which electroluminescence layers 164 and an opposing electrode 166 are formed.

The pixel electrode 162 of each light-emitting element 160 is structured by a plurality of stacked layers. For instance, the pixel electrode 162 may have a structure in which a first conductive layer 162a, a second conductive layer 162b, and a third conductive layer 162c are stacked in this order as shown in FIG. 3. In this case, the electroluminescence layer 164 is in contact with the third conductive layer 162c.

The first conductive layer 162a includes a conductive oxide capable of transmitting visible light, such as a mixed oxide of indium and tin (ITO) and a mixed oxide of indium and zinc (IZO). The second conductive layer 162b is in contact with the first conducive layer 162a and includes a metal with a high reflectance to visible light, such as silver and aluminum, or an alloy including the metal. The second conductive layer 162b functions as a reflective electrode having a function to reflect light generated in the electroluminescence layer 164. The third conductive layer 162c is in contact with the second conductive layer 162b and includes a conductive oxide capable of transmitting visible light, such as ITO and IZO. The third conductive layer 162c not only injects carriers (holes) to the electroluminescence layer 164 but also serves as a light-transmitting electrode to provide a space for resonating the light from the electroluminescence layer 164. Note that it is not always necessary to form the first conductive layer 162a.

Here, the first conductive layers 162a may have the same thickness between the pixels 120 and may exist in the same layer. Similarly, the second conductive layers 162b may have the same thickness between the pixels 120 and may exist in the same layer. On the other hand, the third conductive layers 162c have different thicknesses between the emission regions 159, i.e., between the regions overlapping with the openings of the partition wall 158, in the first light-emitting element 160_1. Specifically, the thickness ti of the third conductive layer 162c in the first emission region 159_1 (the region overlapping with the first opening) is smaller than the thickness t2 of the third conductive layer 162c in the second emission region 159_2 (the region overlapping with the second opening). On the other hand, the thicknesses of the third conductive layers 162c are the same or substantially the same as each other between the second light-emitting element 160_2 and the third light-emitting element 160_3. Namely, the thickness t3 of the third conductive layer 162c in the third emission region 159_3 (the region overlapping with the third opening) is the same or substantially the same as the thickness to of the third conductive layer 162c in the fourth emission region 159_4 (the region overlapping with the fourth opening). Moreover, the thickness t3 and the thickness to are larger than the thickness ti but smaller than the thickness t2. That is, the thicknesses of the third conductive layers 162c possess one of the following relationships in one pixel groups 104.

t₁<t₃=t₄<t₂

t₁<t₃≈t₄<t₂

Here, the thickness of the third conductive layer 162c is assumed to be to (hereinafter, referred to as an optimal thickness) in the case where the element properties are optimized in the first light-emitting element 160_1. In that case, the optimal thickness to is larger than the thickness ti and smaller than the thickness t2. That is, the following relationship is satisfied.

t₁<t₀<t₂

The element properties and their optimal values considered for determining the optimal thickness to may be appropriately selected, and the optimal thickness to is determined in view of the properties such as current efficiency, emission color, viewing-angle dependency, and reliability of the first light-emitting element 160_1.

The electroluminescence layers 164 are each structured by a plurality of functional layers. For example, the electroluminescence layers 164 are structured by appropriately combining, as functional layers, a carrier (hole or electron) injection layer, a carrier-transporting layer, an emission layer, a carrier-blocking layer, an exciton-blocking layer, and the like. An example is shown in FIG. 3 where the light-emitting element 160 of each pixel 120 has a hole-transporting layer HTL, an emission layer EmL, and an electron-transporting layer ETL as typical functional layers. FIG. 3 is illustrated so that the electroluminescence layers 164 are independent between the pixels 120. However, a part of the functional layers may be continuously formed across the first pixel 120_1 to the third pixel 120_3 so as to be shared by these pixels.

The electroluminescence layers 164 may be formed so as to have different structures between the pixels 120. For example, a material or a thickness of the emission layer EmL, a thickness of the hole-transporting layer HTL, a thickness of the electron-transporting layer ETL, or the like may be different between the pixels 120, by which, when the electroluminescence layers 164 included in the first light-emitting element 160_1 to the third light-emitting element 160_3 are defined as a first electroluminescence layer 164_1 to a third electroluminescence layer 164_2, respectively, the pixel group 104 can be configured so that lights with different wavelengths from one another can be obtained from these electroluminescence layers 164. For example, full color display can be achieved by configuring the first electroluminescence layer 164_1 to the third electroluminescence layer 164_3 to emit blue, green, and red lights, respectively.

Here, the structures of the first electroluminescence layers 164_1 are the same between the first emission region 159_1 and the second emission region 159_2 in the first pixel 120_1. Furthermore, the emission wavelength (alternatively, a maximum emission peak wavelength λ₁) of the first electroluminescence layer 164_1 is shorter than the emission wavelengths (alternatively maximum emission peak wavelengths λ₂ and λ₃) of the second electroluminescence layer 164_2 and the third electroluminescence layer 164_3. Any one of the maximum emission peak wavelengths λ₂ and λ₃ may be longer than the other. For example, the electroluminescence layers 164 are configured so that the first electroluminescence layer 164_1 to the third electroluminescence layer 164_3 give blue, green, and red colors, respectively. In this case, the following relationship is established.

The opposing electrode 166 may include a metal such as magnesium, silver, and aluminum or an alloy thereof, for example. Alternatively, the opposing electrode 166 may have a stacked-layer structure of a film including the metal or alloy and a film including a conductive oxide. The opposing electrode 166 not only has a function to inject carriers (electrons) to the electroluminescence layers 164 but also has a function to partly transmit and partly reflect the light from the electroluminescence layers 164. Therefore, when the opposing electrode 166 includes the film containing the metal described above, this film is prepared at a thickness so as to partly transmit visible light. The opposing electrode 160 is also continuously fabricated across the first pixel 120_1 to the third pixel 120_3 and is shared by these pixels.

### 2-3. Suppression of Property Variation of Light-Emitting Element

In each light-emitting element 160, the light emission from the emission layer EmL is reflected at the interfaces between the functional layers in the electroluminescence layer 164, the interface between the electroluminescence layer 164 and the pixel electrode 162, the interface between the electroluminescence layer 164 and the opposing electrode 166, and the interface between the second conductive layer 162b and the third conductive layer 162c, and the reflected lights interfere and resonate with each other. One of the factors which significantly influences this interference effect is the thickness of the electroluminescence layer 164, and variation in thickness of the electroluminescence layer 164 induces variation of a variety of properties (current efficiency, chromaticity, reliability, viewing-angle dependency, and the like) of the light-emitting element 160. Indeed, the inventor confirmed by calculation that deviation in thickness of the electroluminescence layer 164 by 2% to 3% causes deviation in current efficiency by approximately 20% and color coordinates x and y of the light emission by approximately 0.01. Therefore, it is preferred to suppress deviation in thickness of the electroluminescence layer 164 to approximately 1% to 2% in order to produce the display device 100 with small variation in property.

Since the influence of the variation in thickness of the electroluminescence layer 164 increases with decreasing wavelength of the light emission from the emission layer EmL, the influence is largest in the first light-emitting element 160_1 having the shortest emission wavelength. However, the aforementioned structure, that is, the formation of the plurality of emission regions 159 with different thicknesses of the third conductive layers 162c allows reduction of the influence of the variation in thickness of the electroluminescence layer 164_1 of the first light-emitting element 160_1 on the element properties.

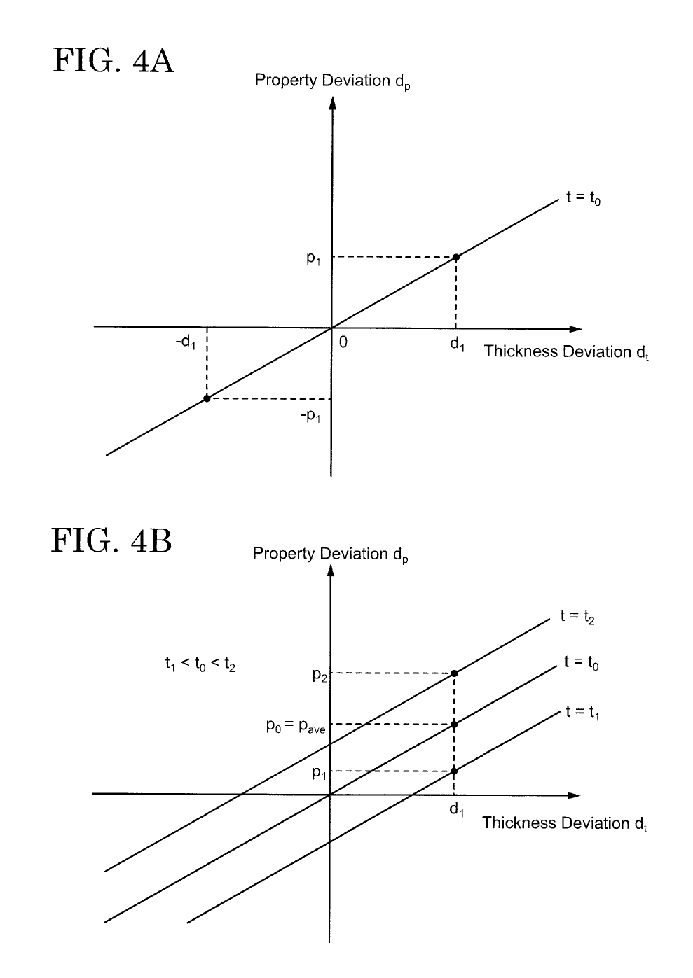

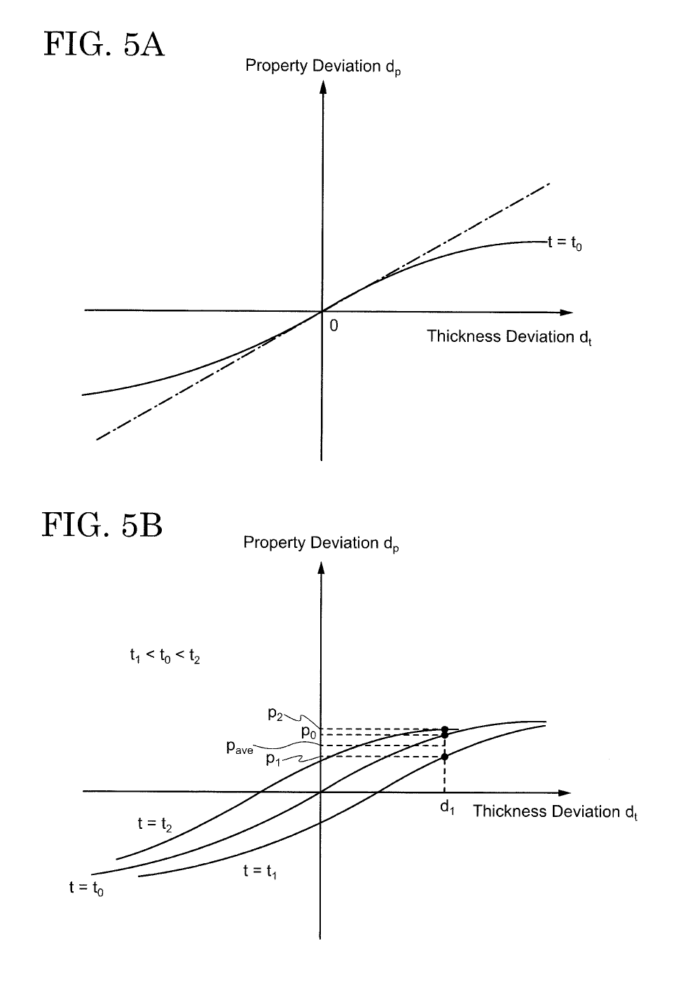

A more specific explanation is made by using FIG. 4A to FIG. 5B. FIG. 4A is a conceptual diagram schematically demonstrating deviation in property (hereinafter, referred to as property deviation) dₚ of the light-emitting element 160 with respect to deviation in thickness of the electroluminescence layer 164 (hereinafter, referred to as thickness deviation) dₜ from a designed value in a case where the thickness t of the third conductive layer 162c is the optimal thickness t₀. When there is no thickness deviation dₜ (dₜ=0), there is no property deviation dₚ of the light-emitting element 160 and dₚ is 0. FIG. 4A illustrates an example where the property deviation dₚ linearly changes with respect to the thickness deviation dₜ. The property deviation dₚ is p₁ when the thickness of the electroluminescence layer 164 is increased to larger than a designed value so that the thickness deviation dₜ is d₁, while the property deviation dₚ is −p₁ when the thickness deviation dₜ is −d₁.

In the light-emitting element 160 giving such characteristics, variation of the thickness t of the third conductive layer 162c causes a shift of the straight line between the thickness deviation and the property deviation (hereinafter, referred to as deviation line). That is, it was confirmed by the inventor that the deviation line shifts to the left or the right when the thickness t becomes larger than (t=t₂) or smaller than (t=t₁) the optimal thickness to, respectively, as shown in FIG. 4B.

As described above, the first light-emitting element 160_1 has two emission regions 159, and the thicknesses of the third conductive layers 162c are different between these regions. Thus, with respect to the deviation line of the case where the thickness t is the optimal thickness t₀, the deviation line of the first emission region 159_1 shifts to the right (t=t₁), while the deviation line of the second emission region 159_2 shifts to the left (t=t₂).

In this case, when the thickness of the first electroluminescence layer 164_1 deviates by d₁, the property deviation dₚ obtained in the first emission region 159_1 becomes p₁ which is smaller than that (p₀) when the thickness t is the optimal thickness t₀. In contrast, the property deviation dₚ obtained in the second emission region 159_2 becomes p₂ which is larger than p₀. Since the areas of the first emission region 159_1 and the second emission region 159_2 are the same in the present embodiment, the contributions of the light emissions from the first emission region 159_1 and the second emission region 159_2 are the same. Hence, these property deviations p₁ and p₂ converge to an averaged value (pₐᵥₑ) in the whole of the first light-emitting element 160_1, and pₐᵥₑ is equal to p₀. Accordingly, the variation in property of the light-emitting element 160_1 resulting from the variation in thickness of the first electroluminescence layer 164_1 can be suppressed to a degree which is substantially the same as that in the case where the third conductive layer 162c has the optimal thickness to.

Additionally, in the case where the property deviation dₚ with respect to the thickness deviation dₜ of the electroluminescence layer 164 does not linearly change but the change in property deviation dₚ decreases with the change in thickness deviation dₜ, the property deviation caused by the thickness deviation of the first electroluminescence layer 164_1 can be more effectively suppressed. The relationship between the thickness deviation and the property deviation in this case is schematically shown in FIG. 5A. As shown in FIG. 5A, a plot of the property deviation dₚ with respect to the thickness deviation dₜ gives a curve (hereinafter, referred to as a deviation curve), and a slope thereof decreases with increasing absolute value of the thickness deviation dₜ.

It was confirmed by the inventor that, in the case of using the light-emitting element with such characteristics, the deviation curve also shifts to the left or the right when the thickness t of the third conductive layer 162c becomes larger than (t=t₂) or smaller than (t=tᵢ) the optimal thickness to of the third conductive layer 162c, respectively (FIG. 5B). Since the thickness t is t₁ in the first emission region 159_1, the obtained property deviation dₚ becomes p₁ which is smaller than that (p₀) in the case where the thickness t is the optimal thickness to when the thickness of the first electroluminescence layer 164_1 deviates by d₁. In contrast, the property deviation dₚ obtained in the second emission region 159_2 becomes p₂ which is larger than p₀. However, a difference between the property deviations p₂ and p₀ is smaller than a difference between the property deviations p₁ and p₀. Hence, the property deviation of the whole of the first light-emitting element 160_1, that is, the averaged value pₐᵥₑ of the property deviations p₁ and p₂ becomes smaller than p₀. In this way, the property deviation dₚ caused by the thickness deviation dₜ of the first electroluminescence layer 164_1 can be smaller than that of the case where the thickness t is optimized.

Since two emission regions 159 of the first light-emitting element 160_1 are close to each other, there is a negligible difference in thickness of the first electroluminescence layer 164_1 in the same pixel group 104. However, the thickness of the first electroluminescence layer 164_1 varies between the different pixel groups 104, between the display devices 100 manufactured over the same mother glass, or between the different substrates 102. The electroluminescence layers 164 are prepared by an evaporation method or an ink-jet method, and it is difficult to precisely control the thickness of the electroluminescence layers 164 (e.g., within 1% to 2%). The influence of the variation in thickness of the electroluminescence layer 164 with a short emission wavelength on the element properties is particularly large and results in a large property variation between display devices.

However, as described above, the use of the structure of the light-emitting element 160 explained in the present embodiment enables suppression of the property variation of the light-emitting element 160 caused by the variation in thickness of the electroluminescence layer 164 giving light emission with a short wavelength. Hence, application of the present embodiment allows production of a display device with reduced property variation.

### Second Embodiment

In the present embodiment, a pixel group 104a with a structure different from that of the pixel group 104 described in the First Embodiment is explained. An explanation regarding the structure the same as or similar to that of the pixel group 104 may be omitted.

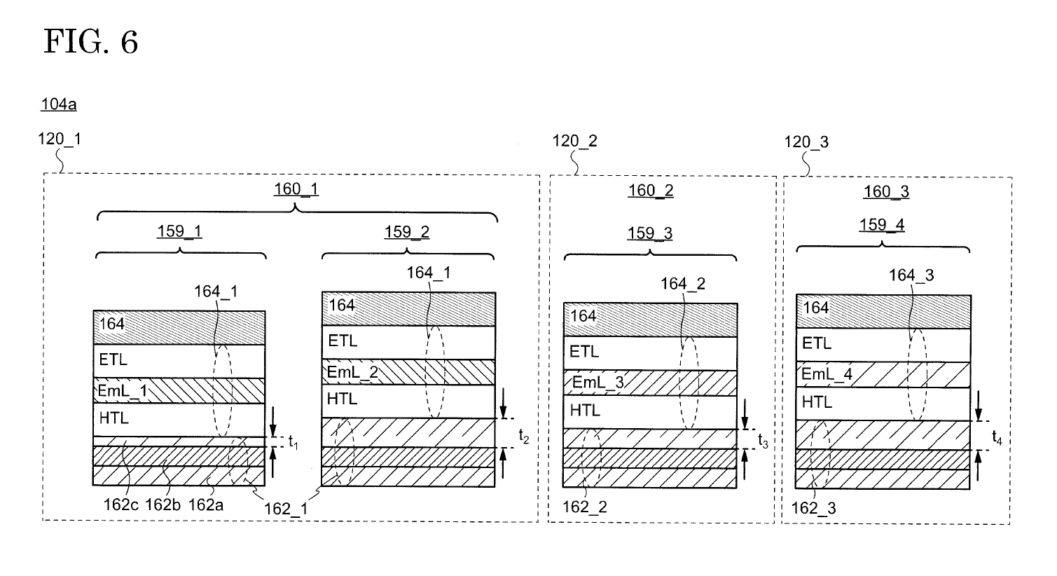

A schematic cross-sectional view of the pixel group 104a according to the present embodiment is shown in FIG. 6. The pixel group 104a is different from the pixel group 104 in that a thickness t₄ of the third conductive layer 162c of the third light-emitting element 160_3 is larger than a thickness t3 of the third conductive layer 162c of the second light-emitting element 160_2. The thickness t3 is larger than the thickness t₁ and smaller than the thickness t₂. On the other hand, the thickness t4 may be the same as, larger than, or smaller than the thickness t₂. Thus, one of the following relationships is satisfied.

t₁<t₃<t₄≤t₂

t₁<t₃<t₂<t₄

When the emission wavelength of the fourth electroluminescence layer 164_4 is longer than that of the third electroluminescence layer 164_3, it is preferred that the optical length of the micro-resonator formed in the third light-emitting element 160_3 be longer than that in the second light-emitting element 160_2, by which the optical adjustment can be more effectively performed in the third light-emitting element 160_3. Hence, the optical adjustment can be more effectively carried out in all of the light-emitting elements 160 by satisfying one of the relationships described above.

### Third Embodiment

In the present embodiment, a structure of the display device 100 and a manufacturing method thereof are explained. An explanation of the contents described in the First and Second Embodiments may be omitted.

### 1. Pixel Circuit

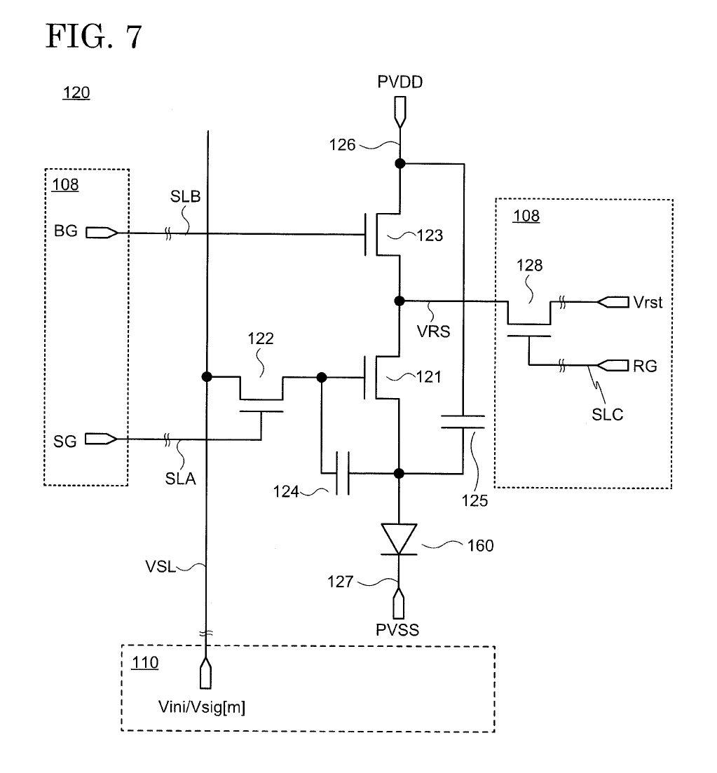

In each pixel 120, a variety of elements for driving the light-emitting element 160 is disposed in addition to the light-emitting element 160, by which a pixel circuit is fabricated. The structure of the pixel circuit may be arbitrarily selected, and an example is shown as an equivalent circuit in FIG. 7.

The pixel circuit shown in FIG. 7 includes a driving transistor 121, a first switching transistor 122, a second switching transistor 123, a storage capacitor 124, and a supplementary capacitor 125 in addition to the light-emitting element 160. The light-emitting element 160 is disposed between a high-potential power-source line 126 and a low-potential power-source line 127. The high-potential power-source line 126 is provided with a high potential PVDD, while the low-potential power-source line 127 is supplied with a low potential PVSS lower than the PVDD.

The driving transistor 121 is arranged between the high-potential power-source line 126 and the light-emitting element 160. The driving transistor 121 possesses a gate as a control terminal and a source and a drain as input-output terminals. In the present embodiment, the driving transistor 121 is regarded as a n-channel type transistor, the input-output terminal electrically connected to the high-potential power-source line 126 is regarded as a drain, and the input-output terminal electrically connected to the light-emitting element 160 is regarded as a source. The drain of the driving transistor 121 is electrically connected to the high-potential power-source line 126 via the second switching transistor 123, and the source is electrically connected to the pixel electrode 162 of the light-emitting element 160.

The gate of the driving transistor 121 is electrically connected to a first signal line VSL via the first switching transistor 122. That is, the first switching transistor 122 is provided between the first signal line VSL and the gate of the driving transistor 121. Operation (on/off) of the first switching transistor 122 is controlled with a scanning signal SG supplied to a first scanning signal line SLA connected to the gate thereof. When the first switching transistor 122 is on, a potential of the first signal line VSL is provided to the gate of the driving transistor 121. An initialization signal Vini and an image signal Vsig are supplied to the first signal line VSL at a predetermined timing. The initialization signal Vini is a signal providing an initialization potential having a constant level. The first switching transistor 122 synchronizes with the first signal line VSL, and on/off is controlled at a predetermined timing to give the gate of the driving transistor 121 with a potential based on the initialization signal Vini or the image signal Vsig.

The driving transistor 121 is connected to the light-emitting element 160 in series via the second switching transistor 123 between the high-potential power-source line 126 and the low-potential power-source line 127. A drain current of the driving transistor 121 is controlled with a voltage of the gate, and a current corresponding to the drain current flows in the light-emitting element 160. Thus, emission intensity of the light-emitting element 160 is controlled by the driving transistor 121.

The storage capacitor 124 is arranged between the source and the gate of the driving transistor 121. The storage capacitor 124 contributes to retention of a voltage between the gate and the source of the driving transistor 121.

A second signal line VRS is electrically connected to the drain of the driving transistor 121. The second signal line VRS is supplied with a reset potential Vrst via a rest transistor 128. A timing of the reset signal Vrst supplied through the reset transistor 146 is controlled by a reset signal RG supplied to a third signal line SLC.

One terminal of the supplementary capacitor 125 is connected to the source of the driving transistor 121, and the other terminal is connected to the high-potential power-source line 126. The supplementary capacitor 125 is provided in order to secure a gate-source voltage Vgs corresponding to the image signal Vsig when the image signal Vsig is supplied to the gate of the driving transistor 121. The supplementary capacitor 125 may be arranged so that the other terminal is connected to the low-potential power-source line 127.

The source-side driver circuit 110 outputs the initialization signal Vini or the image signal Vsig to the first signal line VSL. The gate-side driver circuits 108 output the scanning signal SG, the scanning signal BG, and the reset signal RG to the first scanning line SLA, the second scanning signal line SLB, and the third signal line SLC, respectively. The driver IC 116 outputs a signal for operating the source-side driver circuit 110 and the gate-side driver circuits 108.

### 2. Cross-Sectional Structure

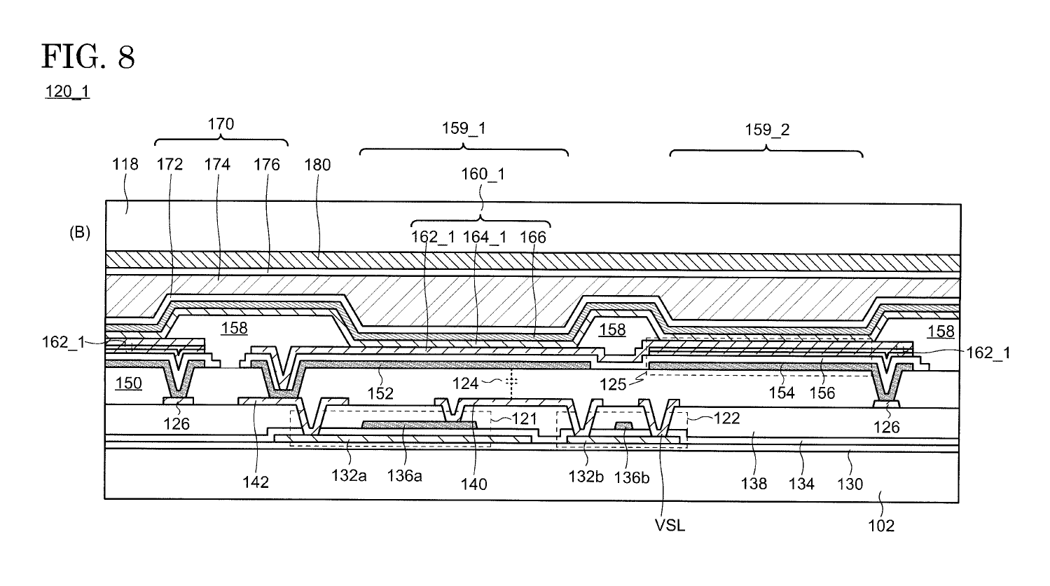

An example of a cross-sectional structure of the first pixel 120_1 is illustrated in FIG. 8. FIG. 8 shows the cross-sectional structures of the driving transistor 121, the first switching transistor 122, the storage capacitor 124, the supplementary capacitor 125, and the light-emitting element 160 in the pixel circuit of the first pixel 120_1. These elements are each formed over the substrate 102 through an undercoat 130.

The driving transistor 121 includes a first semiconductor film 132a, a gate insulating film 134, and a first gate electrode 136a. The gate insulating film 134 is formed to cover the first semiconductor film 132a. The first gate electrode 136a is arranged so as to intersect at least a part of the first semiconductor film 132a with the gate insulating film 134 therebetween. In the driving transistor 121, a channel is formed in a region of the first semiconductor film 132a overlapping with the first gate electrode 136a. Regions of the first semiconductor film 132a other than the region in which the channel is formed function as a source region or a drain region. The source region and the drain region are arranged so as to sandwich the region in which the channel is formed in the first semiconductor film 132a.

An interlayer insulating film 138 is provided over the first gate electrode 136a. The interlayer insulating film 138 is formed so as to extend over the whole of the pixel 120 over which a wiring 142 is disposed. The wiring 142 is connected to the source region or the drain region of the first semiconductor film 132a through a contact hole passing through the interlayer insulating film 138 and the gate insulating film 134.

The first switching transistor 122 includes a second semiconductor film 132b, the gate insulating film 134, and a second gate electrode 136b. Although the second semiconductor film 132b exists in the same layer as the first semiconductor film 132a, they are separated from each other. As shown in the equivalent circuit of FIG. 7, one of a source region and a drain region corresponding to an input-output terminal of the first switching transistor 122 is connected to the first gate electrode 136a of the driving transistor 121 through a wiring 140, and the other is connected to the first signal line VSL. The wiring 140 and the first signal line VSL are prepared with the same conductive layer as the wiring 142. Moreover, the high-potential power-source line 126 existing in the same layer as the wiring 142 is disposed over the interlayer insulating film 138. Hence, all of the wiring 140, the first signal line VSL, the wiring 142, and the high-potential power-source line 126 exist in the same layer.

A silicon semiconductor such as amorphous silicon or polysilicon or a metal oxide exhibiting semiconductor properties is applied to the first semiconductor film 132a and the second semiconductor film 132b. Typically, the former is prepared with a chemical vapor deposition (CVD) method, while the latter is prepared with a sputtering method. The undercoat 130, the gate insulating film 134, and the interlayer insulating film 138 may include a silicon-containing inorganic compound such as silicon oxide and silicon nitride and may be formed by applying a sputtering method or a CVD method.

The first gate electrode 136a, the second gate electrode 136b, the wiring 140, the wiring 142, the first signal line VSL, and the high-potential power-source line 126 are structured with a metal such as copper, molybdenum, tantalum, tungsten, and aluminum or an alloy thereof and are formed with a sputtering method, a CVD method, or the like. A stacked-layer structure in which a metal with a high-melting point, such as titanium, molybdenum, and tungsten, is provided over and under a highly conductive metal such as aluminum and copper may be employed for these electrodes and wirings.

A leveling film 150 is arranged over the wiring 140 and the wiring 142. The leveling film 150 embeds the wiring 140 and the wring 142 to provide a flat surface. The leveling film 150 may be formed with an organic insulating material such as a polyimide, an acrylic resin, or an epoxy resin. The leveling film 150 is formed with a coating method, an evaporative polymerization method, a printing method, or the like by using a monomer or oligomers of the organic insulating material.

A conductive film 152 and a conductive film 154 are arranged on a top surface of the leveling film 150. These films may exist in the same layer, may include a material usable in the first gate electrode 136a and the second gate electrode 136b, and may have a structure the same as or similar to those of the first gate electrode 136a and the second gate electrode 136b.

A dielectric film 156 is formed over the conductive layers 152 and 154 over which the pixel electrode 162 is arranged. The dielectric film 156 may include an inorganic insulating material such as silicon nitride and is formed with a CVD method. The pixel electrode 162 is connected to the conductive film 152 through a contact hole provided in the dielectric film 156. The conductive film 152 is connected to the wiring 142 through a contact hole formed in the leveling film 150 and overlaps at least partly with the wiring 140 with the leveling film 150 sandwiched therebetween. Hence, the pixel electrode 162 and the conductive film 152 are equipotential.

The conductive film 154 is covered by the pixel electrode 162 through the dielectric film 156 and is arranged in a region which does not overlap with the first gate electrode 136a. The conductive film 154 is connected to the high-potential power-source line 126 through a contact hole formed in the leveling film 150.

The conductive film 152 overlaps with the wiring 140 through the leveling film 150, thereby forming the storage capacitor 124. Here, although the conductive film 152 also overlaps with the pixel electrode 162 through the dielectric film 156, substantially no capacitance is formed therebetween because the conductive film 152 and the pixel electrode 162 are electrically connected to each other so as to be equipotential. On the other hand, the conductive film 154 overlaps with the pixel electrode 162 through the dielectric film 156 to form the supplementary capacitor 125. The conductive film 154 has the same potential as the high-potential power-source line 126 but does not form parasitic capacitance because the conductive film 154 does not overlap with the wiring 140 nor the first gate electrode 136a.

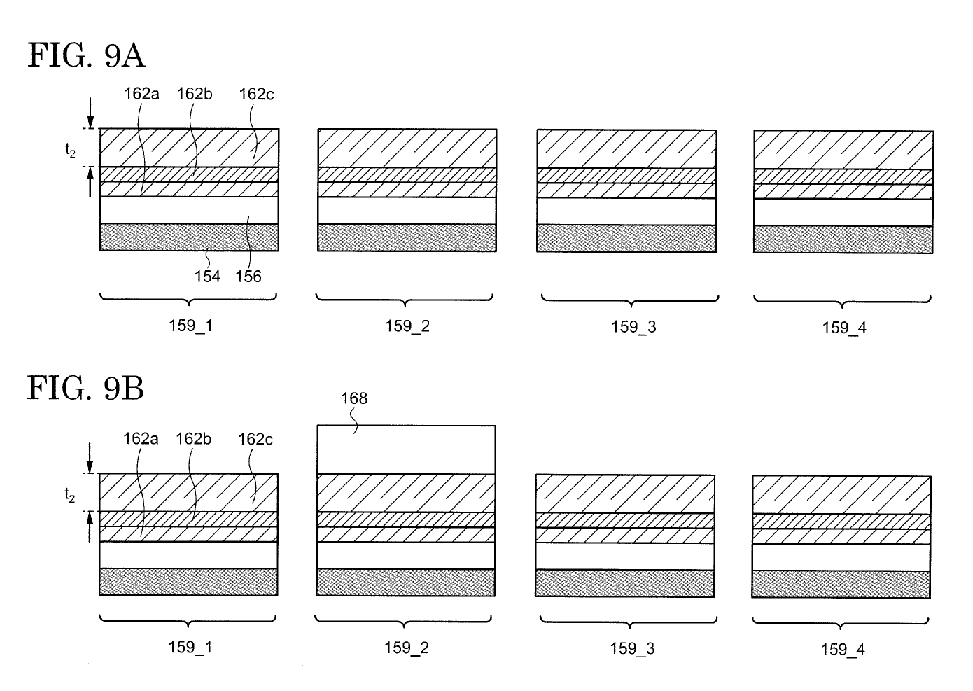

The pixel electrode 162 is formed according to the following method, for example. First, after forming the contact hole in the dielectric film 156, the first conductive layer 162a, the second conductive layer 162b, and the third conductive layer 162c are sequentially formed over substantially the whole of the substrate 102. These films may be formed with a sputtering method or a CVD method. After that, these layers are simultaneously patterned to remove the first conductive layer 162a, the second conductive layer 162b, and the third conductive layer 162c which are formed in an unnecessary region (that is, a region in which the pixel electrode 162 is not formed). The state at this stage is shown in FIG. 9A. Here, schematic cross-sectional views of the first emission region 159_1 to the fourth emission region 159_4 are illustrated. The film-formation conditions and the etching conditions are selected so that the thicknesses t of the third conductive layers 162c at this stage are the thickness t₂ of the third conductive layer 162c in the second emission region 159_2.

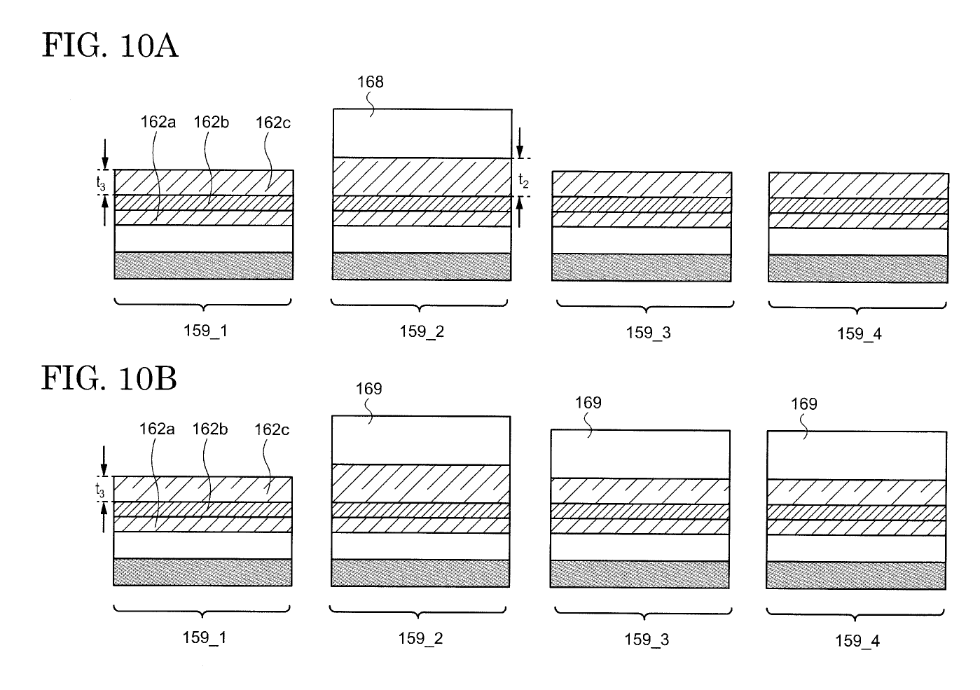

After that, a resist mask 168 is formed so as to cover the third conductive layer 162c formed over the second emission region 159_2 (FIG. 9B), and the third conductive layers 162c are subjected to etching processing so that the thicknesses of the third conductive layers 162c in the first emission region 159₋1, the third emission region 159_3, and the fourth emission region 159_4 become t₃ (or t₄) (FIG. 10A). Note that, although not illustrated, the resist mask 168 is preferably formed so as to cover a top surface and a side surface of the third conductive layer 162c formed in the second emission region 159_2, by which partial loss (side etching) of the second conductive layers 162b can be prevented.

After that, the resist mask 168 is removed, and a resist mask 169 covering the second emission region 159_2 to the fourth emission region 159_4 is formed (FIG. 10B). The resist mask 169 may be formed without removing the resist mask 168. At this stage, it is preferred to form the resist mask 169 so as to cover top surfaces and side surfaces of the third conductive layers 162c in the second emission region 159_2 to the fourth emission region 159_4 in order to prevent side etching of the second conductive layers 162b.

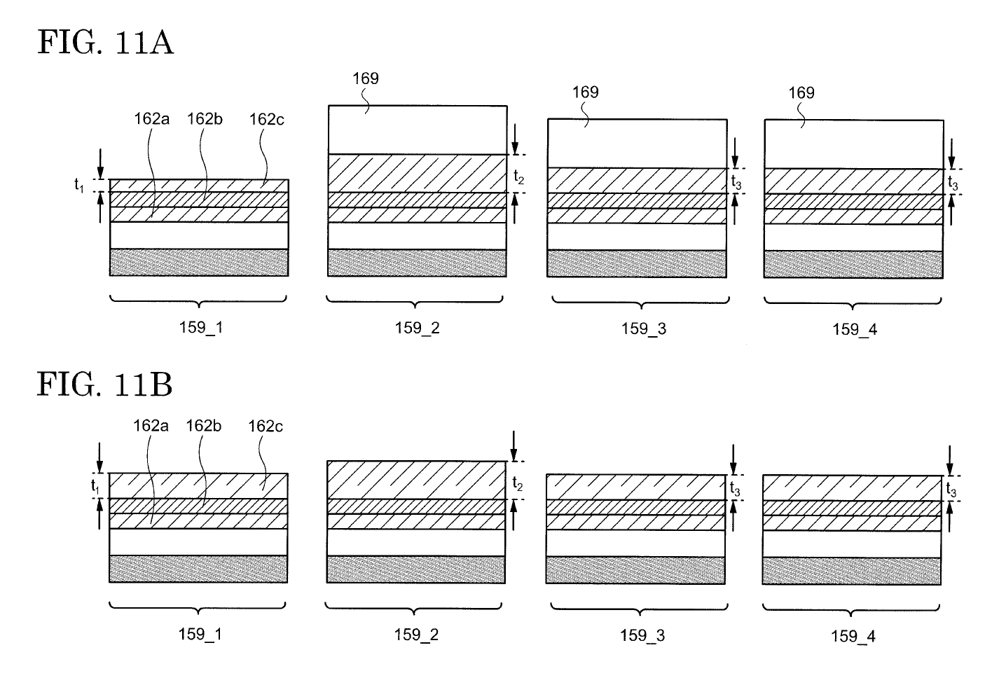

Etching is carried out again in this state to perform thinning so that the thickness of the third conductive layer 162c positioned in the first emission region 159_1 becomes ti (FIG. 11A). After that, the resist mask 169 is removed, resulting in the formation of the third conductive layers 162c having thicknesses t₁, t₂, t₃, and t₃ (or t₁, t₂, t₄, and t₄) in the first emission region 159_1 to the fourth emission region 159_4, respectively (FIG. 11 B). Since the second conductive layers 162b which are relatively readily oxidized in the etching process are not exposed to an etchant in this method, it is possible to maintain the high reflectance of the second conductive layers 162b.

After forming the pixel electrode 162, the partition wall 158 is formed so as to cover the edge portion of the pixel electrode 162 (FIG. 8). The partition wall 158 has the openings exposing top surfaces of the pixel electrode 162, and the openings correspond to the emission regions 159 in which the electroluminescence layer 164 is in contact with the pixel electrode 162. It is preferred that an edge portion of the openings of the partition wall 158 have an inclined surface. The partition wall 158 is prepared with an organic insulating material such as an epoxy resin or an acrylic resin.

Next, the electroluminescence layer 164 is arranged to cover the pixel electrode 162 and the partition wall 158. The opposing electrode 166 is arranged over the electroluminescence layer 164. The light-emitting element 160 is structured by the pixel electrode 162, the electroluminescence layer 164, and the opposing electrode 166. The electroluminescence layer 164 is formed by appropriately using an evaporation method, an ink-jet method, a spin-coating method, and the like.

A protection film (hereinafter, referred to as a passivation film) 170 for protecting the light-emitting elements is disposed over the light-emitting elements 160 as an optional structure. The structure of the passivation film 170 may be arbitrarily selected, and a stacked-layer structure possessing a first layer 172 containing an inorganic compound, a second layer 174 containing an organic compound, and a third layer 176 containing an inorganic compound may be applied to the passivation film 170 as shown in FIG. 8. In this case, the aforementioned inorganic compound containing silicon may be used as an inorganic compound. A polymer material such as an epoxy resin or an acrylic resin may be used as an organic compound.

The second layer 174 may have a relatively large thickness, by which depressions and projections caused by the partition wall 158 are absorbed to provide a flat top surface, and the third layer 176 can be formed thereover. Therefore, planarity of the third layer 176 is improved, and generation of a crack or a pinhole in the third layer 176 can be prevented, thereby effectively preventing entrance of impurities.

A resin layer 180 is disposed over the passivation film 170. The resin layer 180 is a layer used as a mask to expose the terminals 112 by removing, with etching, the first layer 172 and the third layer 176 formed over the terminals 112 and has a function to protect the passivation film 170 in the etching process. The resin layer 180 includes a polymer material such as an acrylic resin or an epoxy resin.

An opposing substrate 118 is fixed to the substrate 102 with an adhesive layer which is not illustrated so as to sandwich the pixel circuit including the light-emitting element 160, by which the pixel circuit is sealed. Although not illustrated, a touch sensor may be fabricated between the passivation film 170 and the resin layer 180.

### Fourth Embodiment

In the present embodiment, a pixel group 104b with a structure different from those of the pixel groups 104 and 104a described in the First and Second Embodiments is explained. An explanation regarding the contents the same as or similar to those described in the First to Third Embodiments may be omitted.

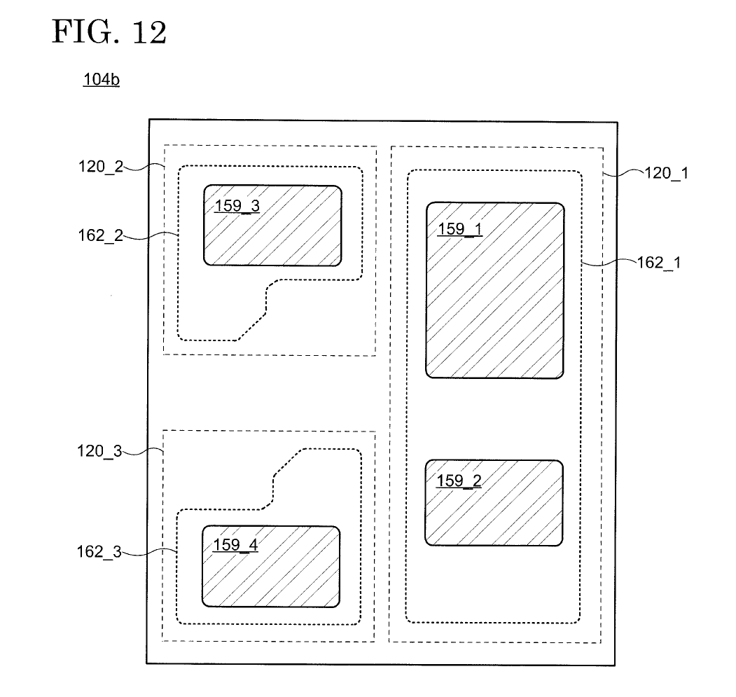

A schematic top view of the pixel group 104b is shown in FIG. 12. The pixel group 104b is different from the pixel groups 104 and 104a in that the area of the first emission region 159_1 is larger than that of the second emission region 159_2. Similar to the pixel groups 104 and 104a, the thickness t₁ of the third conductive layer 162c in the first emission region 159_1 is smaller than that (t₂) in the second emission region 159_2. Moreover, the thickness t₃ of the third conductive layer 162c of the second pixel electrode 162_2 and the thickness to of the third conductive layer 162c of the third pixel electrode 162_3 are larger than the thickness t₁ and smaller than the thickness t₂.

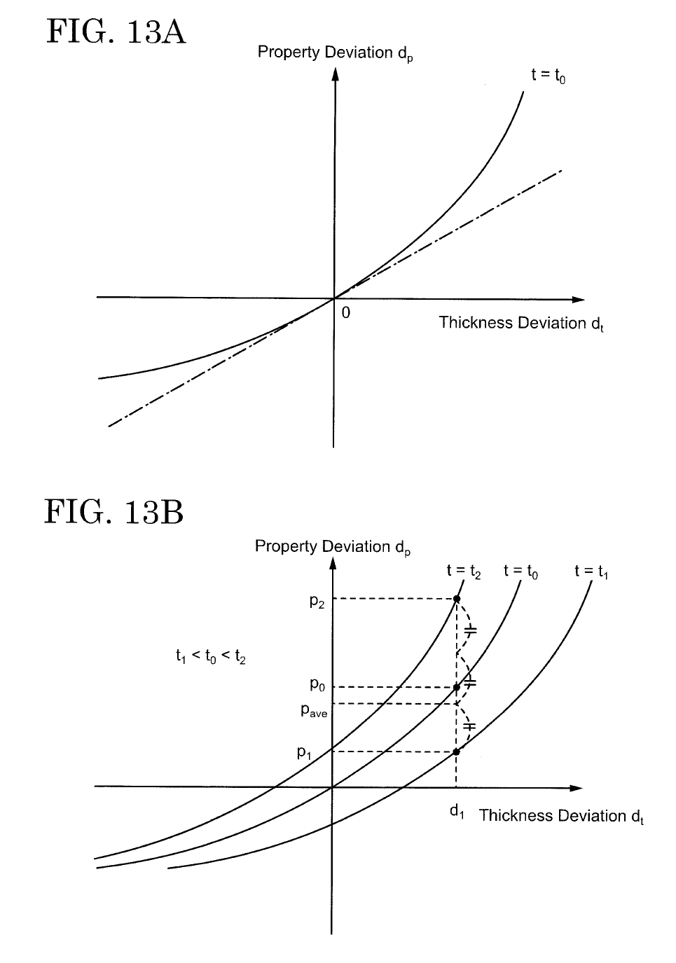

The pixel group 104b with such a structure is particularly effective for the case where the change in property deviation dₚ with respect to the thickness deviation dₜ of the electroluminescence layer 164 increases with increasing thickness deviation dₜ and is capable of more effectively suppressing the variation in property caused by the variation in thickness of the electroluminescence layer 164. The relationship between the thickness deviation and the property deviation in this case is schematically shown in FIG. 13A. As shown in FIG. 13A, a plot of the property deviation dₚ of the light-emitting element 160 with respect to the thickness deviation dₜ of the electroluminescence layer 164 gives a curve (hereinafter, referred to as a deviation curve), and a slope thereof increases with increasing absolute value when the thickness deviation dₜ is positive and decreases with increasing absolute value when the thickness deviation dₜ is negative.

It was also confirmed for this case by the inventor that, as shown in FIG. 13B, the deviation curve respectively shifts to the left or the right when the thickness t of the third conductive layer 162c becomes larger than (t=t₂) or smaller than (t=t₁) the optimal thickness t₀. Note that the inventor further confirmed that many light-emitting elements 160 exhibit such a deviation curve.

When the thickness of the first electroluminescence layer 164_1 deviates by d₁, the obtained property deviation dₚ becomes p₁ which is smaller than that (p₀) at the time when the thickness t of the third conductive layer 162c is the optimal thickness t₀ because the thickness t of the third conductive layer 162c is t₁ in the first emission region 159_1. In contrast, the property deviation dₚ obtained in the second emission region 159_2 becomes p₂ which is larger than p₀. In addition, a difference between the property deviations p₂ and p₀ is larger than a difference between the property deviations p₁ and p₀.

However, the contribution of the first electroluminescence layer 164_1 is larger than the contribution of the second electroluminescence layer 164_2 because the area of the first emission region 159_1 is larger than that of the second emission region 159_2. When the area of the first emission region 159_1 is twice the area of the second emission region 159_2, the property deviation pₐᵥₑ of the whole of the first light-emitting element 160_1 is a weighted average considering the areas and obeys the following equation.

$${P}_{ave} = \frac{2 {p}_{1} + {p}_{2}}{3}$$

This property deviation is extremely small compared with a property deviation expected from a simple arithmetic average (pₐᵥₑ=(p₁+p₂)/2). Therefore, the variation in element property caused by the variation in thickness of the first electroluminescence layer 164_1 can be smaller than that when the thickness t of the third conductive layer 162c is the optimal thickness t₀.

The inventor revealed that, in a great number of light-emitting elements, the influence of the thickness deviation dₜ of the third conductive layer 162c on the property deviation dₚ is small as shown in FIG. 13A and FIG. 13B, when the thickness of the electroluminescence layer is smaller than a designed value. Therefore, the property deviation dₚ of the light-emitting element is small and can be ignored in the display device 100 according to the present embodiment in the case where the thickness deviation dₜ of the electroluminescence layer is negative. On the other hand, the influence of the thickness deviation dₜ of the third conductive layer 162c on the property deviation dₚ is large when the thickness deviation is positive (FIG. 13A and FIG. 13B). However, the use of the structure described in the present embodiment prevents a significant change in element property even if the thickness of the electroluminescence layer 164 deviates toward a positive direction. Hence, it is possible to produce a display device with reduced variation and afford a wide margin to a manufacturing method of the display device.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

In the specification, although the cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

What is claimed is:

1. A light-emitting element comprising:
a reflective electrode;
a light-transmitting electrode over the reflective electrode;
a partition wall over the light-transmitting electrode, the partition wall having a first opening and a second opening which overlap with the light-transmitting electrode;
an electroluminescence layer over the first opening and the second opening; and
an opposing electrode over the electroluminescence layer,
wherein a thickness of the light-transmitting electrode in a region overlapping with the first opening is smaller than a thickness of the light-transmitting electrode in a region overlapping with the second region.

2. The light-emitting element according to claim 1,
wherein a structure of the electroluminescence layer in the region overlapping with the first opening is the same as a structure of the electroluminescence layer in the region overlapping with the second opening.

3. The light-emitting element according to claim 1,
wherein an area of the first opening is smaller than an area of the second opening.

4. The light-emitting element according to claim 1,
wherein the electroluminescence layer is configured to be blue-emissive.

5. A display device comprising:
a first pixel and a second pixel,
wherein:
the first pixel comprises:
a first reflective electrode;
a first light-transmitting electrode over the first reflective electrode;
a partition wall over the first light-transmitting electrode, the partition wall having a first opening and a second opening which overlap with the first light-transmitting electrode;
a first electroluminescence layer overlapping with the first opening and the second opening; and
an opposing electrode overlapping with the first electroluminescence layer;
the second pixel comprises:
a second reflective electrode;
a second light-transmitting electrode over the second reflective electrode;
a second electroluminescence layer over the second light-transmitting electrode; and
the opposing electrode overlapping with the second electroluminescence layer;
a thickness of the first light-transmitting electrode in a region overlapping with the first opening is smaller than a thickness of the second light-transmitting electrode; and
the thickness of the second light-transmitting electrode is larger than a thickness of the first light-transmitting electrode in a region overlapping with the second opening.

6. The display device according to claim 5,
wherein a structure of the first electroluminescence layer in the region overlapping with the first opening is the same as a structure of the first electroluminescence layer in the region overlapping with the second opening.

7. The display device according to claim 5,
wherein an area of the first opening is smaller than an area of the second opening.

8. The display device according to claim 5,
wherein the first electroluminescence layer and the second electroluminescence layer are configured to emit light with a first wavelength and a second wavelength, respectively, and
the first wavelength is shorter than the second wavelength.

9. The display device according to claim 5,
wherein the first electroluminescence layer is configured to be blue-emissive.

10. A display device comprising:
a first pixel, a second pixel, and a third pixel, wherein:
the first pixel comprises:
a first reflective electrode;
a first light-transmitting electrode over the first reflective electrode;
a partition wall over the first light-transmitting electrode, the partition wall having a first opening and a second opening which overlap with the first light-transmitting electrode;
a first electroluminescence layer overlapping with the first opening and the second opening; and
an opposing electrode over the first electroluminescence layer;
the second pixel comprises:
a second reflective electrode;
a second light-transmitting electrode over the second reflective electrode;
a second electroluminescence layer over the second light-transmitting electrode; and
the opposing electrode overlapping with the second electroluminescence layer;
the third pixel comprises:
a third reflective electrode;
a third light-transmitting electrode over the third reflective electrode;
a third electroluminescence layer over the third light-transmitting electrode; and
the opposing electrode over the third electroluminescence layer;
a thickness of the first light-transmitting electrode in a region overlapping with the first opening is smaller than a thickness of the second light-transmitting electrode; and
the thickness of the second light-transmitting electrode is larger than a thickness of the first light-transmitting electrode in a region overlapping with the second opening.

11. The display device according to claim 10,
wherein a thickness of the third light-transmitting electrode is larger than the thickness of the first light-transmitting electrode in the region overlapping with the first opening and smaller than the thickness of the first light-transmitting electrode in the region overlapping with the second opening.

12. The display device according to claim 11,
wherein the thickness of the third light-transmitting electrode is larger than the thickness of the second light-transmitting electrode.

13. The display device according to claim 10,
wherein a structure of the first electroluminescence layer in the region overlapping with the first opening is the same as a structure of the first electroluminescence layer in the region overlapping with the second opening.

14. The display device according to claim 10,
wherein an area of the first opening is larger than an area of the second opening.

15. The display device according to claim 14,
wherein the partition wall is located between the second light-transmitting electrode and the second electroluminescence layer and between the third light-transmitting electrode and the third electroluminescence layer and has a third opening overlapping with the second light-transmitting electrode and a fourth opening overlapping with the third light-transmitting electrode, and
an area of the third opening is the same as an area of the fourth opening.

16. The display device according to claim 10,
wherein the first electroluminescence layer, the second electroluminescence layer, and the third electroluminescence layer are configured to emit lights with a first wavelength, a second wavelength, and a third wavelength, respectively, and
the first wavelength is shorter than the second wavelength and the third wavelength.

17. The display device according to claim 10,
wherein the first electroluminescence layer, the second electroluminescence layer, and the third electroluminescence layer are configured to emit blue light, green light, and red light, respectively.
